(19) United States
(12) Patent Application Publication
(10) Pub. No.: US 2026/0005492 A1
(43) Pub. Date: Jan. 1, 2026

(54) MICRO VERTICAL-CAVITY SURFACE-EMITTING LASER (VCSEL) WITH INTEGRATED THERMAL MANAGEMENT

(71) Applicant: Intel Corporation, Santa Clara, CA (US)

(72) Inventors: Khaled Ahmed, San Jose, CA (US); Benjamin T. Duong, Phoenix, AZ (US)

(73) Assignee: Intel Corporation, Santa Clara, CA (US)

(21) Appl. No.: 18/759,854

(22) Filed: Jun. 29, 2024

(51) Int. Cl. H01S 5/183; H01S 5/024; H01S 5/10; H01S 5/343; H01S 5/42

(52) U.S. Cl. CPC H01S 5/18377; H01S 5/02469; H01S 5/1067; H01S 5/18394; H01S 5/343; H01S 5/423

(57) ABSTRACT

Devices and systems with lasers, such as vertical-cavity surface-emitting lasers (VCSELs), and methods of forming the same, are disclosed herein. In one example, a laser includes multiple mirrors and one or more quantum wells between the mirrors, where the mirrors include at least one metasurface mirror.

### BACKGROUND

Vertical-cavity surface-emitting lasers (VCSELs) are a type of semiconductor laser diode with laser light emission perpendicular to the surface of the chip rather than from the edge. For data communication applications, arrays of small VCSELs, referred to as micro-VCSELs, can be used to transfer data in parallel between two chips. Micro-VCSELs face various thermal management challenges, however, which can degrade performance. For example, a VCSEL typically includes two distributed Bragg reflectors (DBRs) positioned above and below the active region where light is generated, thus reflecting light back and forth between the mirrors through the active region to achieve lasing. Current flowing through the DBRs generates heat, however, which causes the VCSEL threshold to shift with time, and shift of the threshold results in a reduction of optical power, which causes data transmission errors.

### BRIEF DESCRIPTION OF THE DRAWINGS

FIG. 1 illustrates a cross-section view of a micro vertical-cavity surface-emitting laser (VCSEL) array with metasurface mirrors and integrated heat sinks.

FIGS. 2A-M illustrate a process flow for forming a micro-VCSEL array with metasurface mirrors and integrated heat sinks.

FIG. 3 illustrates a cross-section view of a micro-VCSEL array with thermal vias.

FIGS. 4A-J illustrate a process flow for forming a micro-VCSEL array with thermal vias.

FIG. 5 illustrates a cross-section view of a micro-VCSEL array with liquid cooling channels.

FIGS. 6A-D illustrate a process flow for forming a micro-VCSEL array with liquid cooling channels.

FIG. 7 illustrates a perspective view of a micro-VCSEL array with liquid cooling channels.

FIGS. 8A-B illustrate plan views of micro-VCSEL arrays with integrated heat sinks.

FIG. 9 illustrates a cross-section view of a system with a micro-VCSEL array according to certain embodiments.

FIG. 10 illustrates a top view of a wafer and dies that may be included in a microelectronic assembly.

FIG. 11 illustrate a cross-sectional side view of an integrated circuit device assembly that may include a microelectronic assembly.

FIG. 12 illustrates a block diagram of an example electrical device that may include a microelectronic assembly.

### DETAILED DESCRIPTION

Vertical-cavity surface-emitting lasers (VCSELs) are a type of semiconductor laser diode with laser light emission perpendicular to the surface of the chip rather than from the edge. For data communication applications, arrays of small VCSELs, referred to as micro-VCSELs, may be used to transfer data in parallel between two chips (e.g., using 32×32 micro-VCSEL arrays). While the use of micro-VCSELs results in reduction of relative intensity noise (RIN) compared to large VCSELs, thermal management is necessary to meet system performance requirements under operating conditions. However, current thermal management solutions are insufficient for dense arrays of micro-VCSELs.

In particular, a VCSEL typically includes two distributed Bragg reflectors (DBRs) positioned above and below the active region or layer where light is generated, thus reflecting the light back and forth between the mirrors through the active region to achieve lasing. Current flowing through the DBRs generates heat, however, which causes the VCSEL threshold to shift with time, and shift of the threshold results in a reduction of optical power, which causes data transmission errors.

In some embodiments, micro-VCSELs may be flip-chip transferred from a growth wafer to a CMOS “backplane” that drives each individual micro-VCSEL as needed. In one configuration, backside emission is used, and micro-VCSELs cannot emit light with wavelengths below 900 nanometers (nm) as the wavelength will not travel through the substrate due to the gallium arsenide (GaAs) transmission curve, and applications based on wavelength less than 900 nm cannot use these micro-VCSELs (e.g., data communication applications require wavelengths lower than 900 nm to illuminate in a range sensitive to inexpensive CMOS camera or sensor technology). In this configuration, heat generated in the active area needs to be dissipated through the gallium arsenide (GaAs) substrate. However, gallium arsenide (GaAs) is a poor thermal conductor (0.55 W/cm-° C.). This in effect traps the heat being generated on or near the active area, thereby quickly “heating” such devices up to elevated temperatures, which begins to severely impair operational characteristics. Moreover, VCSEL devices can be fabricated with very high density, which exasperates the problem, as the thermal resistance for smaller micro-VCSELs increases by a factor of more than 5× compared to large VCSELs. When heat is trapped, the operating temperature is higher, which degrades the modulation frequency of the VCSEL.

In some cases, a single heat sink may be used below the VCSELs for heat dissipation. While this may be feasible for large VCSELs and less-dense arrays of VCSELs, the heat dissipation efficiency decreases as the VCSEL size and pitch is scaled (e.g., due to high thermal resistance). As a result, this approach is insufficient for dense arrays of micro-VCSELs.

Accordingly, this disclosure presents embodiments of micro-VCSEL arrays for optical communication and input/output (I/O), with metasurface mirrors and integrated thermal management mechanisms, including heat sinks, thermal vias, and liquid cooling channels.

In some embodiments, for example, a micro-VCSEL array may include a dense array of ultrasmall VCSELs with at least one metasurface mirror around the active region instead of two DBR mirrors. A metasurface mirror is a thin, tunable structure that generates less heat than a thick DBR mirror, which reduces the amount of heat generated by the VCSELs. Moreover, the integrated thermal management mechanisms (e.g., heat sinks, thermal vias, liquid cooling channels) also help dissipate the heat. As a result, the micro-VCSEL array has more efficient thermal management, which enables lower operating temperatures and higher performance (e.g., faster optical I/O speeds).

Various techniques and structures are presented to sink heat generated from each micro-VCSEL in a densely packed array. For example, a bottom-emitting micro-VCSEL array (e.g., bottom emitting in the fabricated orientation, top emitting in the transferred configuration) may be coupled to a separate heat spreading superstrate that may be positioned above the apertures of the array and that may be able to transmit the emitted beams through the heat spreading superstrate. The micro-VCSEL devices in the dense array may be controlled by separate electrical connection between the anode of an individual device and a driving circuit (e.g., transconductor), but electrically isolated from, the heat spreading superstrate. After transferring the micro-VCSELs to a CMOS drive backplane, the superstrate may be bonded to the to the emitter array assembly. The superstrate may be a cost effective thermally and or electrically conductive material with one or more large holes for laser emissions without requiring close alignment.

The described embodiments may provide various advantages, including more efficient thermal management and heat dissipation for dense micro-VCSEL arrays, thus enabling high-speed micro-VCSEL arrays for parallel optical I/O with extended operating temperature ranges.

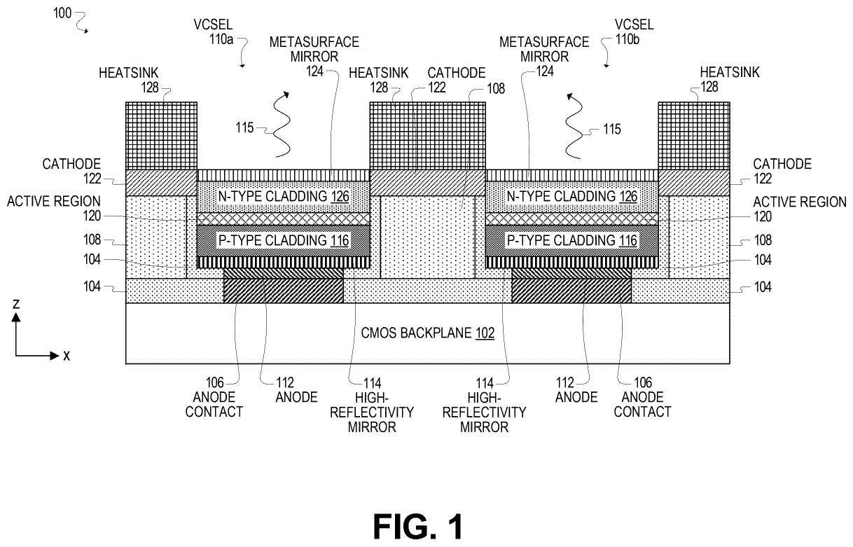

FIG. 1 illustrates a cross-section view (x-z plane) of an example micro vertical-cavity surface-emitting laser (VCSEL) array 100 with metasurface mirrors 124 and integrated heat sinks 128. In the illustrated embodiment, VCSEL array 100 includes an array of micro-VCSELs 100a,b with integrated heat sinks 128 on a complementary metal-oxide-semiconductor (CMOS) backplane 102. The respective micro-VCSELs 100a,b include an active region 120 (e.g., one or more quantum wells for generating light 115) positioned between two mirrors 114, 124. The top mirror 124 is a metasurface mirror with high reflectivity (e.g., at least ˜95% reflectivity in some embodiments), and the bottom mirror 114 is another high-reflectivity mirror with even higher reflectivity (e.g., ˜99-100% reflectivity in some embodiments). In some embodiments, the bottom mirror 114 may be a distributed Bragg reflector (DBR) mirror or another metasurface mirror. With the higher reflectivity mirror 114 below the active region 120 and the (slightly) lower reflectivity mirror above the active region 120, the VCSELs 110a,b are designed to emit laser beams 115 vertically in the upwards direction (e.g., perpendicular to the top surface of the VCSEL array 100). Moreover, the integrated heat sinks 128 include openings over the regions where the VCSELs 100a,b emit light 115.

In this configuration, the VCSEL array 100 has very effective heat dissipation. For example, heat generated in the bottom mirror 114 (e.g., a DBR or metasurface mirror) is dissipated downward through the anodes 112, while heat generated in the top metasurface mirror 124 is dissipated upward through the cathodes 122 and the integrated heat sinks 128. Moreover, since the top mirror 124 is a metasurface mirror (e.g., instead of a DBR mirror), significantly less heat is generated in the top mirror 124 compared to a typical DBR mirror. In particular, metasurface mirrors are extremely thin mirrors with planar (e.g., single layer) arrangements of nanoparticles, while DBR mirrors are relatively thick mirrors with stacks of alternating layers of multiple materials. As a result, DBR mirrors have much higher thermal resistance than metasurface mirrors, which causes more heat to be generated in DBR mirrors compared to metasurface mirrors.

In this manner, VCSEL array 100 dissipates heat more effectively than traditional VCSEL arrays with two DBR mirrors, which enables VCSEL array 100 to maintain a lower operating temperature, and thus higher performance, by avoiding the performance degradations caused by overheating.

The elements of VCSEL array 100 will now be described in further detail.

The CMOS backplane 102 may include one or more semiconductor or integrated circuit dies with CMOS logic or driver circuitry to control the VCSELs 110a,b and cause emission of laser beams 115. In the illustrated embodiment, the CMOS backplane 102 includes a dielectric layer 104 with anode contacts 106, which are hybrid bonded to the dielectric layers 104, 108 and anode contacts 112 in the VCSEL array 100.

The micro-VCSELs 110a,b may be referred to throughout this disclosure as micro-VCSELs, VCSELs, surface-emitting lasers, lasers, laser devices, etc. In the illustrated embodiment, the respective VCSELs 110a,b include an anode contact 112, a high-reflectivity bottom mirror 114 (e.g., DBR or metasurface mirror), p-type cladding 116 (e.g., p-type gallium nitride (GaN), gallium arsenide (GaAs)), an active region 120, n-type cladding 126 (e.g., n-type gallium nitride (GaN), gallium arsenide (GaAs)), a top metasurface mirror 124, and a cathode 122.

The active region 120 may be referred to throughout this disclosure as the active region, active layer, active laser medium, quantum well(s), multiple quantum well (MQW), etc. In some embodiments, the active region 120 may include one or more quantum wells for generating light 115, which may be thin layers of semiconductor material where electron-hole recombination occurs. Quantum wells may be designed with specific energy levels to optimize the emission wavelength and efficiency of lasers. A multiple quantum well (MQW) may refer to a semiconductor structure including multiple thin, periodic layers (e.g., quantum wells) of one material between barriers of another material with a larger bandgap. This configuration may confine carriers (e.g., electrons and holes) in the quantum wells, which may lead to discrete energy states. When light is generated by the active region 120, the respective mirrors 114, 124 around the active region 120 reflect the light back and forth through the active region 120, enabling the light to gain sufficient energy for lasing.

A metasurface (MS) mirror (e.g., metasurface mirror 124, and optionally mirror 114) may be referred to throughout this disclosure as a metasurface mirror, a metamirror (MM), a reflective metasurface, etc.

A metasurface mirror (MSM) may refer to a type of metasurface having properties that can be used to manipulate light. For example, a metasurface mirror may include a thin, planar array of sub-wavelength-scale structures, referred to as nanoparticles or meta-atoms, arranged on a surface or substrate with properties (e.g., geometry, arrangement, material composition) that can be tuned to reflect, manipulate, or control light (e.g., reflect light in specific directions to focus or disperse the light). In particular, the geometry (e.g., size, dimensions, shape), arrangement (e.g., spacing or distance between nanoparticles, periodic versus aperiodic nanoparticle arrangements, periodicity), and material composition of the nanoparticles can be tuned to engineer the reflective behavior of the metasurface mirror.

Metasurface mirrors are based on the principles of metasurfaces and metamaterials. For example, a metamaterial is a three-dimensional (3D) material engineered with certain properties to manipulate electromagnetic waves, a metasurface is a two-dimensional (2D) equivalent of a metamaterial, and a metasurface mirror is a particular type of metasurface whose properties are used to manipulate light.

A metasurface mirror (e.g., mirror 124 and optionally mirror 114) may be made of any suitable materials depending on the desired optical/reflective properties, including, without limitation: metals such as gold (Au), silver (Ag), aluminum (Al), copper (Cu), and titanium (Ti); dielectrics and semiconductors such as silicon (Si), silicon nitride (e.g., SiN, Si3N4), silicon oxide (e.g., SiO, SiO2), titanium oxide (e.g., TiO, TiO2), gallium nitride (GaN), gallium arsenide (GaAs), and indium phosphide (InP); polymers such as polydimethylsiloxane (PDMS) and polymethyl methacrylate (PMMA); and compounds and composites of any of the foregoing materials, such as metal-dielectric composites (e.g., a metal layer combined with a dielectric spacer), nanoparticles (e.g., made of any of the foregoing materials) embedded in polymers, etc. Thus, in various embodiments, a metasurface mirror may include elements such as gold, silver, aluminum, copper, titanium, silicon, gallium, indium, nitrogen, oxygen, arsenic, and/or phosphorous (e.g., silicon and nitrogen, silicon and oxygen, titanium and oxygen, gallium and nitrogen, gallium and arsenic, indium and phosphorous).

A DBR mirror (e.g., optionally mirror 114) may refer to a mirror that includes multiple layers of alternating materials with different refractive indices.

The anode contacts 106, 112 may be conductive contacts, such as metal hybrid bond interconnect (HBI) pads (e.g., copper (Cu) pads).

The cathode contacts 122 may be conductive contacts coupled to ground.

The laser beams 115 emitted by the VCSELs 110a,b may be referred to throughout this disclosure as laser beams, light beams, lasers, optical signals, etc.

The heat sink(s) 128 may include any suitable material for dissipating heat (e.g., a metal such as aluminum). In some embodiments, the heat sinks 128 may be a metal layer patterned with holes over the VCSELs 110a,b to form openings or apertures in the areas where laser beams 115 are emitted.

Dielectric layer 104 may be made of any suitable dielectric, such as a thermally-conductive dielectric (e.g., a dielectric material with high thermal conductivity, such as alumina or aluminum nitride (AlN)). In some embodiments, dielectric layer 104 may be used as a dielectric spacer that facilitates heat transmission from the active region 120 into the cathode 122, which in turn is thermally coupled to the heat sinks 128, thus dissipating the heat.

Dielectric layer 108 may be made of any suitable dielectric, including, without limitation, carbon-doped oxide, silicon dioxide (SiO₂), silicon nitride, and silicon oxy nitride.

It should be appreciated that micro-VCSEL array 100 is merely shown as an example and numerous variations and alternative embodiments are also possible within the scope of this disclosure. In various embodiments, for example, certain elements of VCSEL array 100 may be modified, replaced, rearranged, omitted, and/or added. As an example, VCSEL array 100 may include any number of VCSELs 110 and heat sinks 128 in various embodiments. In some embodiments, the heat sinks 128 may be omitted and/or replaced with other thermal management components (e.g., thermal vias 322 and/or liquid cooling channels 528). As another example, certain elements of VCSEL array 100 may be made of materials other than those described above, or they may have different arrangements than those shown in FIG. 1. VCSEL array 100 may also include a variety of other components not shown in the illustrated embodiment.

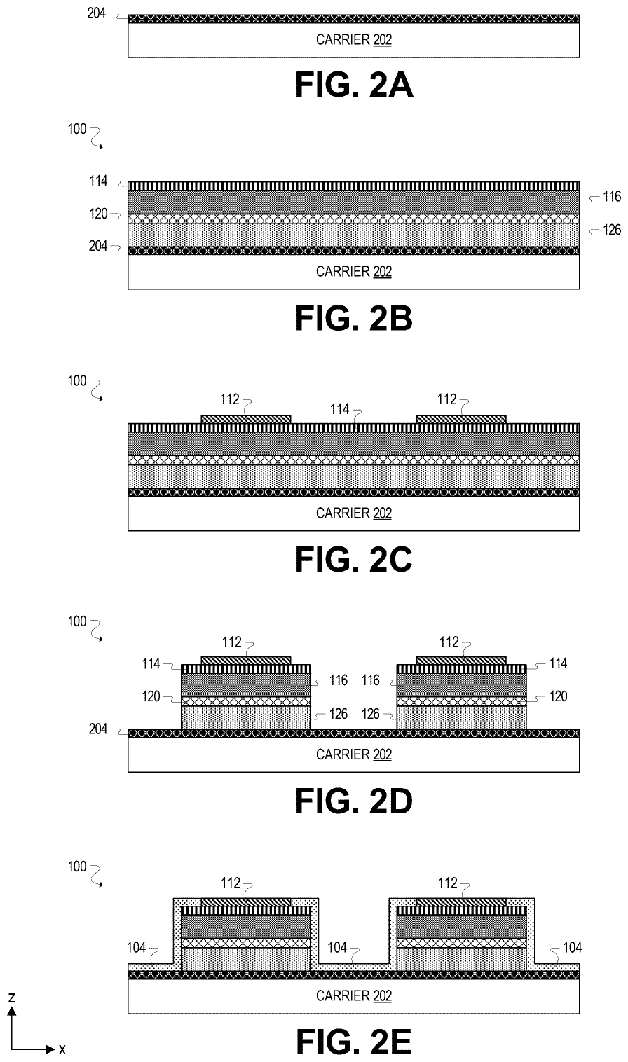

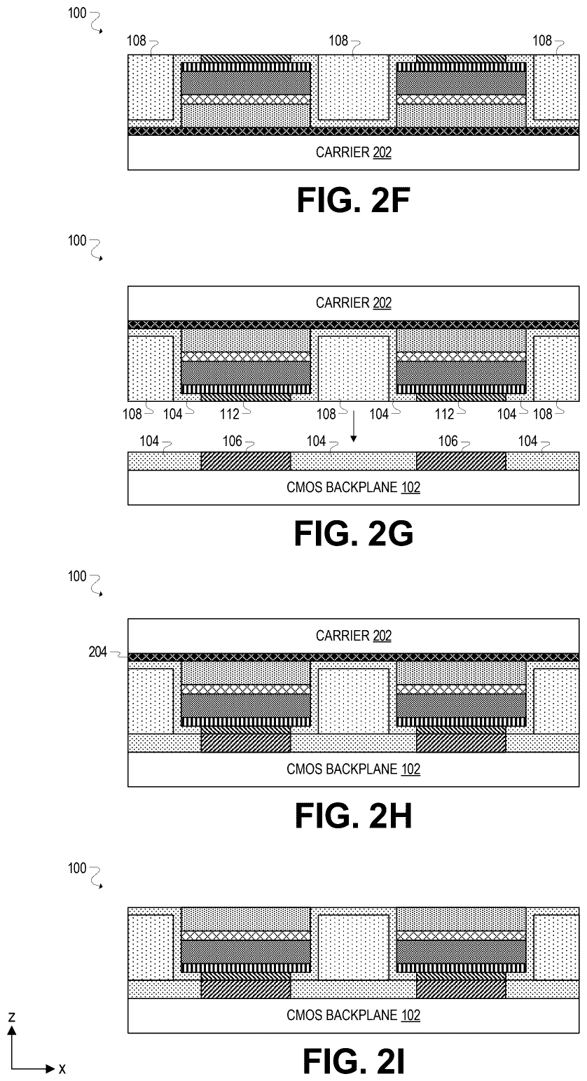

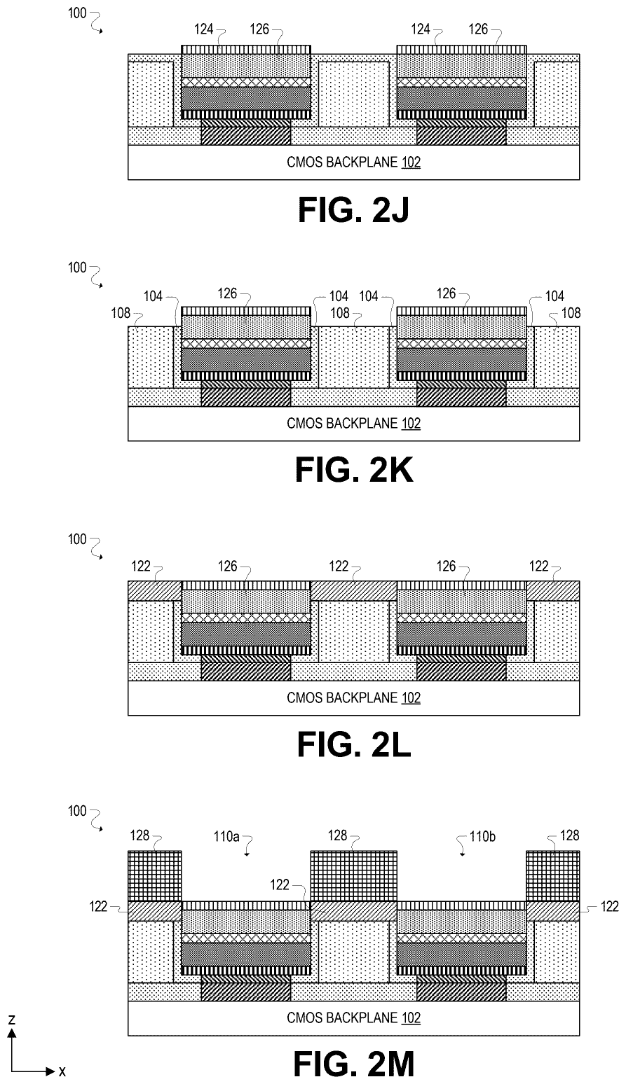

Additional embodiments of VCSEL arrays and associated processing are described in connection with FIGS. 2-9 (including with respect to VCSEL arrays 300, 500, 700, 800a,b, 910). The concepts described above with respect to VCSEL array 100, including any modifications and variations thereof, also apply to the other embodiments of VCSELs and VCSEL arrays described throughout this disclosure, and vice versa.

FIGS. 2A-M illustrate an example process flow for forming a micro-VCSEL array 100 with metasurface mirrors 124 and integrated heat sinks 128. In the illustrated example, FIGS. 2A-M show cross-section views (x-z plane) after each step of the process flow. It will be appreciated in light of the present disclosure that the illustrated process flow is only one example methodology for arriving at micro-VCSEL array 100.

In FIG. 2A, a carrier substate 202 is received (e.g., a sapphire wafer), and a release layer 204 is formed over the carrier substrate 202.

In FIG. 2B, layers of n-type cladding 126, quantum wells 120, p-type cladding 116, and a high-reflectivity mirror 114 (e.g., DBR or metasurface mirror with ˜99-100% reflectivity) are formed over the release layer 204 on the carrier substrate 202 (e.g., via epitaxial growth).

In FIG. 2C, anode contacts 112 are formed over the high-reflectivity mirror layer 114 by depositing and patterning an anode metal.

In FIG. 2D, micro-VCSEL stacks are singulated by dry etching the n-type cladding 126, quantum well 120, p-type cladding 116, and high-reflectivity mirror 114 layers down to the release layer 204 to form mesas of micro-VCSEL stacks. In some embodiments, a passivation treatment may be applied to the sidewalls to repair defects due to etching or oxidation to define apertures of the micro-VCSELs.

In FIG. 2E, a thermally conductive dielectric layer 104 is formed over the VCSEL stacks by depositing a high-thermal-conductivity dielectric (e.g., using atomic layer deposition (ALD)) and patterning the resulting dielectric layer 104 to expose the anode contacts 112.

In FIG. 2F, a dielectric layer 108 is formed between the VCSEL stacks by depositing a fill dielectric (e.g., with high thermal conductivity) and polishing the surface (e.g., using chemical mechanical polishing (CMP)).

In FIG. 2G, the carrier substrate 202 is flipped over and hybrid bonded face down to a CMOS backplane substrate 102. In particular, a hybrid dielectric-to-dielectric and metal-to-metal bond is formed between (i) the dielectric layers 104, 104 and (ii) the anode contacts 106, 112 on the CMOS substrate 102 and the carrier 202, respectively. In this manner, the anodes 112 on the VCSELs 110a,b are electrically coupled to the anode contacts 106 on the CMOS backplane 102 (thus electrically coupling the array of VCSELs 110a,b to the CMOS backplane 102 via hybrid dielectric and metal bonds).

The resulting hybrid bonded substrate 100 is shown in FIG. 2H.

In FIG. 2I, the growth substrate 202 is removed (e.g., via laser ablation of the release layer 204), and the underlying surface is cleaned.

In FIG. 2J, metasurface mirrors 124 with high reflectivity (e.g., ˜95% or higher in some embodiments) are formed over the n-type cladding 126 by depositing and patterning the appropriate materials, arrangements, and design of nanoparticles.

In FIG. 2K, portions of the dielectric layers 104, 108 are etched (e.g., wet/dry etch) to expose the n-type cladding 126 (e.g., for the cathodes 122 formed in FIG. 2L).

In FIG. 2L, cathode metal contacts 122 are formed in the etched regions adjacent to the exposed n-type cladding 126 by depositing a cathode metal through a mask (e.g., using physical vapor deposition (PVD)).

In FIG. 2M, integrated heat sinks 128 are formed over the VCSELs 110a,b and on top of the cathodes 122 (e.g., by depositing a metal and patterning the metal layer with holes to form openings or apertures over the respective VCSELs 110a,b where light is emitted).

At this point, the process flow may be complete. The completed VCSEL array 100 is shown in FIG. 2M.

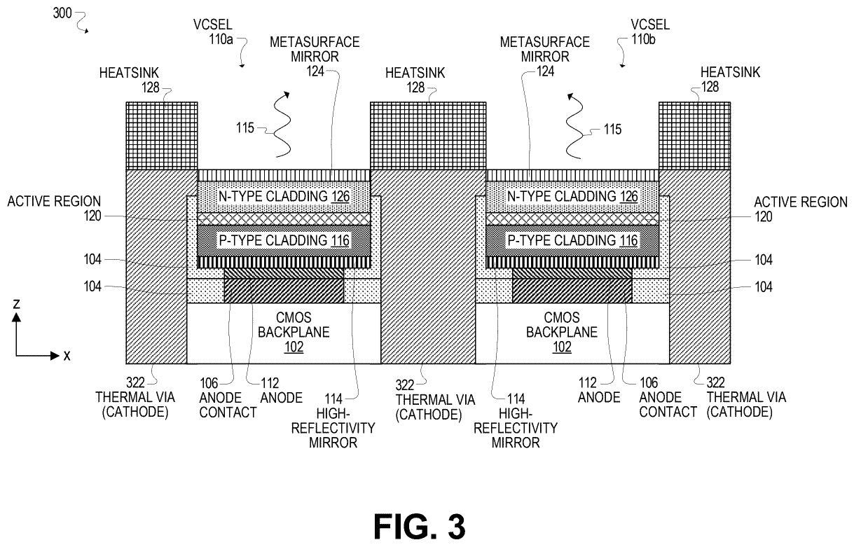

FIG. 3 illustrates a cross-section view (x-z plane) of an example micro-VCSEL array 300 with thermal vias 322 between micro-VCSELs 110a,b. In the illustrated embodiment, VCSEL array 300 is similar to VCSEL array 100 (e.g., an array of VCSELs 110a-b with one or more metasurface mirrors 124), except VCSEL array 300 includes thermal vias 322 between VCSELs 110a,b-which also function as cathodes-instead of the cathodes 122 and fill dielectric 108 of VCSEL array 100. In particular, the thermal vias 322 are positioned between VCSELs 110a,b and under the integrated heat sinks 128, extending vertically through the VCSEL array 300 from the underlying CMOS backplane 102 up to the integrated heat sinks 128. In this manner, the thermal vias 322 facilitate efficient heat transfer from the CMOS backplane 102 (or any other underlying die or substrate) to the above heat sinks 128. Moreover, the thermal vias 322 may also be coupled to ground (e.g., through ground contacts (not shown) below the thermal vias 322), thus functioning as cathodes for the VCSELs 110a,b.

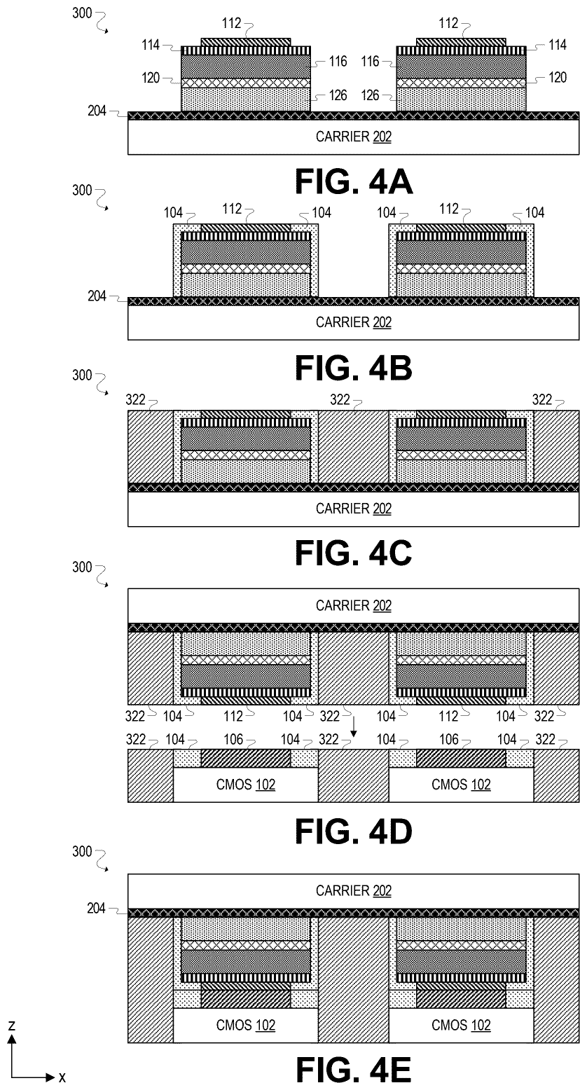

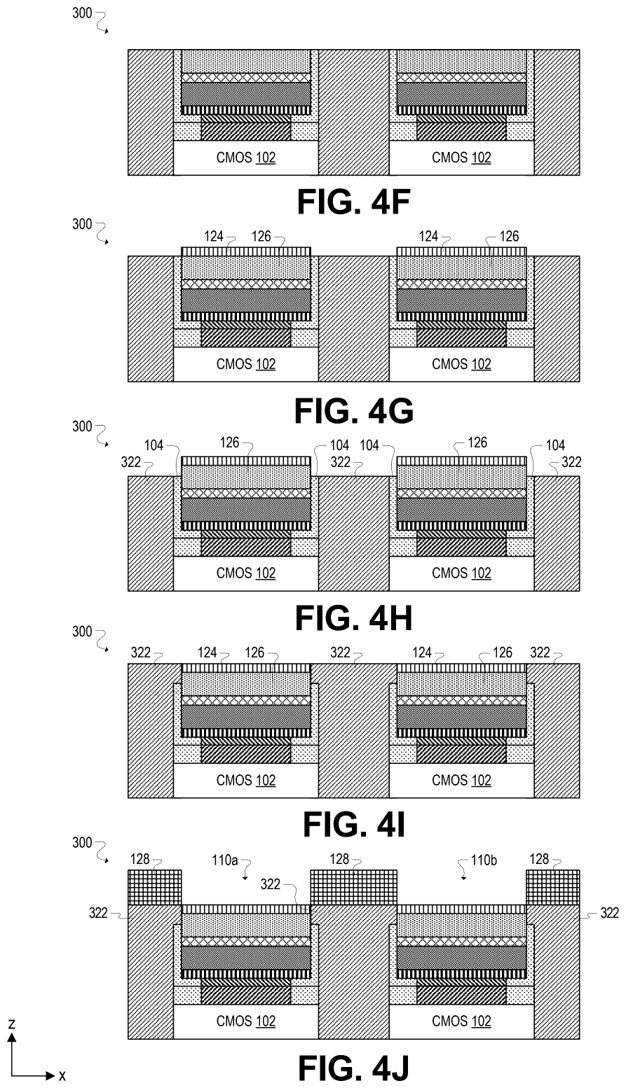

FIGS. 4A-J illustrate an example process flow for forming a micro-VCSEL array 300 with thermal via cathodes 322 between micro-VCSELs 110a,b. In the illustrated example, FIGS. 4A-J show cross-section views (x-z plane) after each step of the process flow. It will be appreciated in light of the present disclosure that the illustrated process flow is only one example methodology for arriving at micro-VCSEL array 300.

In some embodiments, the beginning of the process flow for VCSEL array 300 may be similar to the portions of the process flow for VCSEL array 100 shown in FIGS. 2A-D. As a result, the details of those portions of the process flow are omitted for simplicity.

Accordingly, in FIG. 4A, the VCSEL array 300 is shown with anodes 112, high-reflectivity mirrors 114, p-type cladding 116, n-type cladding 126, and active regions 120, which are formed on a release layer 204 of a carrier substrate 202 (e.g., similar to the VCSEL array 100 shown in FIG. 2D).

In FIG. 4B, a thermally conductive dielectric layer 104 is formed on the VCSEL stacks by depositing a high-thermal-conductivity dielectric (e.g., using atomic layer deposition (ALD)) and patterning the dielectric layer 104 to expose the anode contacts 112 and the base of the carrier substrate 202 (e.g., the release layer 204).

In FIG. 4C, thermal vias 322 are formed in the etched regions between the VCSEL stacks by depositing a fill metal and polishing the surface (e.g., using chemical mechanical polishing (CMP)). As discussed previously, these thermal vias 322 will also serve as cathodes/ground contacts in the completed VCSEL array 300.

In FIG. 4D, the carrier substrate 202 is flipped over and hybrid bonded face down to a CMOS backplane substrate 102, which includes corresponding thermal vias 322. In particular, a hybrid dielectric-to-dielectric and metal-to-metal bond is formed between (i) the dielectric layers 104, 104, (ii) the anode contacts 106, 112, and (iii) the thermal vias 322 on the CMOS substrate 102 and carrier 202.

The resulting hybrid bonded substrate 300 is shown in FIG. 4E.

In FIG. 4F, the growth substrate 202 is removed (e.g., via laser ablation of the release layer 204), and the underlying surface is cleaned.

In FIG. 4G, metasurface mirrors 124 with high reflectivity (e.g., ˜95% or higher) are formed over the n-type cladding 126 by depositing and patterning the appropriate materials, arrangements, and design of nanoparticles.

In FIG. 4H, portions of the thermally conductive dielectric layers 104 and the thermal vias 322 are etched (e.g., wet/dry etch) to expose the n-type cladding 126 (e.g., thus enabling the thermal vias 322 to be extended up to the exposed n-type cladding 126 to serve as the cathodes, as shown in FIG. 4I).

In FIG. 4I, the thermal vias 322 are extended up to the exposed n-type cladding 126 (and metasurface mirrors 124) to enable them to serve as cathode metal contacts (e.g., by building up/depositing additional fill metal over the thermal vias 322).

In FIG. 4J, integrated heat sinks 128 are formed over the VCSELs 110a,b and on top of the thermal vias/cathodes 322 (e.g., by depositing a metal and patterning the metal layer with holes to form openings or apertures over the respective VCSELs 110a,b where light is emitted).

At this point, the process flow may be complete. The completed VCSEL array 300 is shown in FIG. 4J.

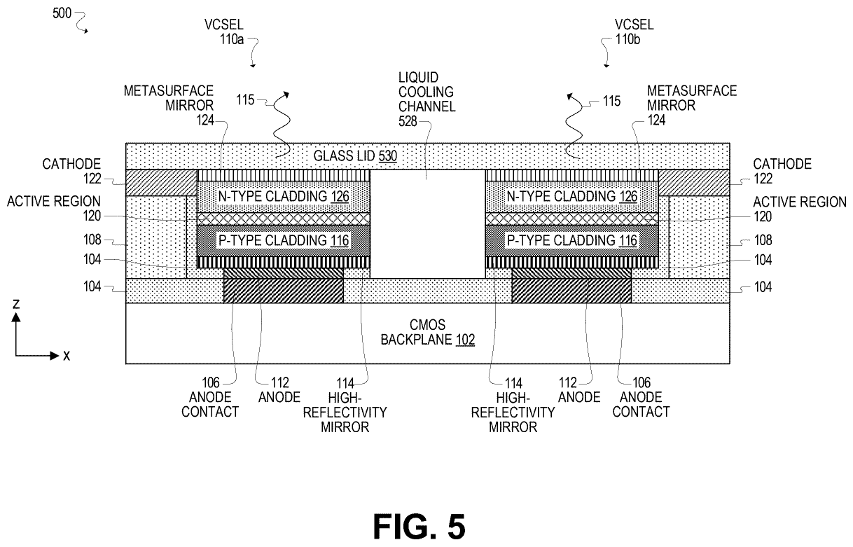

FIG. 5 illustrates a cross-section view (x-z plane) of an example micro-VCSEL array 500 with liquid cooling channels 528 between micro-VCSELs 110a,b. In the illustrated embodiment, VCSEL array 500 is similar to VCSEL array 100 (e.g., an array of VCSELs 110a-b with one or more metasurface mirrors 124), except VCSEL array 500 includes liquid cooling channels 528 between VCSELs 110a,b, along with a glass lid 530 over the channels 528, for efficient heat dissipation instead of integrated heat sinks 128.

In some embodiments, the liquid cooling channels 528 may include hollow passages between VCSELs 110a,b that extend through the VCSEL array 700, with openings on each end of the respective channels 528 to enable liquid to flow in and out, thus cooling the VCSELs 110a,b. In the illustrated example, only one liquid cooling channel 528 and two VCSELs 110a,b are shown for simplicity. In actual embodiments, however, VCSEL array 500 may include any number of VCSELs 110 and corresponding liquid cooling channels 528.

In the illustrated embodiment, the glass lid 530 is positioned on top of VCSEL array 500, thus covering the top of the channels 528 to seal them off and prevent liquid from escaping, while also allowing light beams 115 emitted by VCSELs 110a,b to penetrate through the lid 530. In some embodiments, for example, the glass lid 530 may be a glass substrate that light is capable of penetrating through. Further, in some embodiments, the glass lid 530 may include additional features (not shown), such as lenses to manipulate the light beams 115 emitted by VCSELs 110a,b.

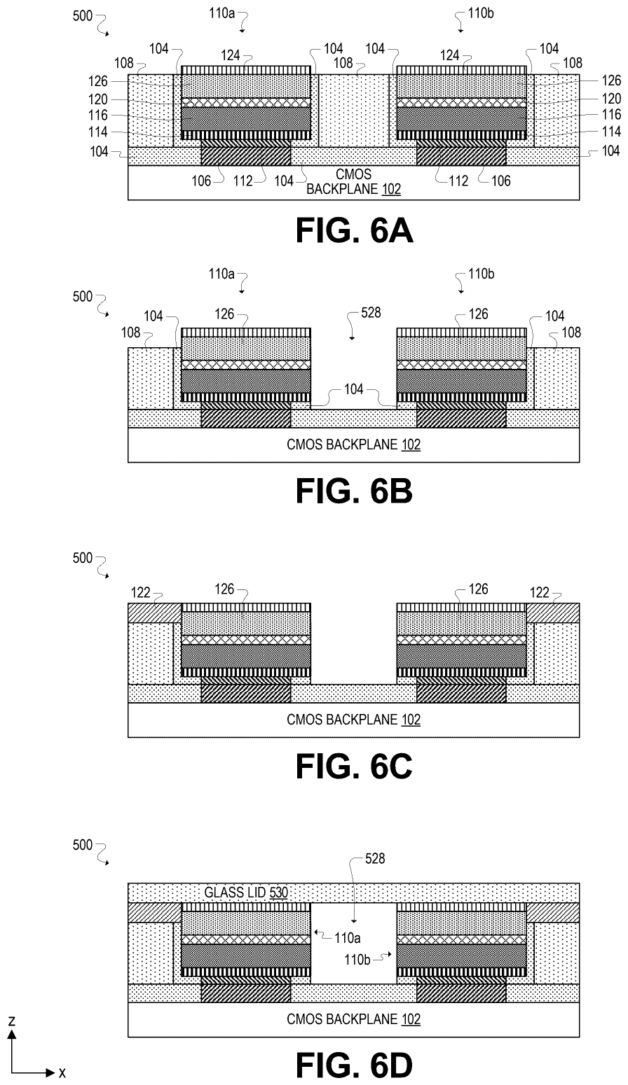

FIGS. 6A-D illustrate an example process flow for forming a micro-VCSEL array 500 with liquid cooling channels 528 between micro-VCSELs 110. In the illustrated example, FIGS. 6A-D show cross-section views (x-z plane) after each step of the process flow. It will be appreciated in light of the present disclosure that the illustrated process flow is only one example methodology for arriving at micro-VCSEL array 500.

In some embodiments, the beginning of the process flow for VCSEL array 500 may be similar to the portions of the process flow for VCSEL array 100 shown in FIGS. 2A-J. As a result, the details of those portions of the process flow are omitted for simplicity.

Accordingly, in FIG. 6A, the VCSEL array 500 is shown with CMOS backplane 102, anode contacts 106, dielectrics 104, 108, VCSELs 110a,b, anodes 112, high-reflectivity mirrors 114, metasurface mirrors 124, p-type cladding 116, n-type cladding 126, and active regions 120 (e.g., similar to the VCSEL array 100 shown in FIG. 2J).

In FIG. 6B, portions of the dielectric layers 104, 108 are etched (e.g., wet/dry etch) to expose the n-type cladding 126 (e.g., for the cathodes 122 formed in FIG. 6C) and form cooling channels 528 between VCSELs 110a,b.

In FIG. 6C, cathode metal contacts 122 are formed in the etched regions adjacent to the exposed n-type cladding 126 by depositing a cathode metal through a mask (e.g., using physical vapor deposition (PVD)).

In FIG. 6D, the glass lid 530 is assembled on top of the VCSEL array 500 to close off the cooling channels 528. In some embodiments, the glass lid 530 may include various features (not shown), such as lenses, to manipulate beams emitted by the VCSELs 110a,b and assist with functions such as beam profiling, steering, and so forth.

At this point, the process flow may be complete. The completed VCSEL array 500 is shown in FIG. 6D.

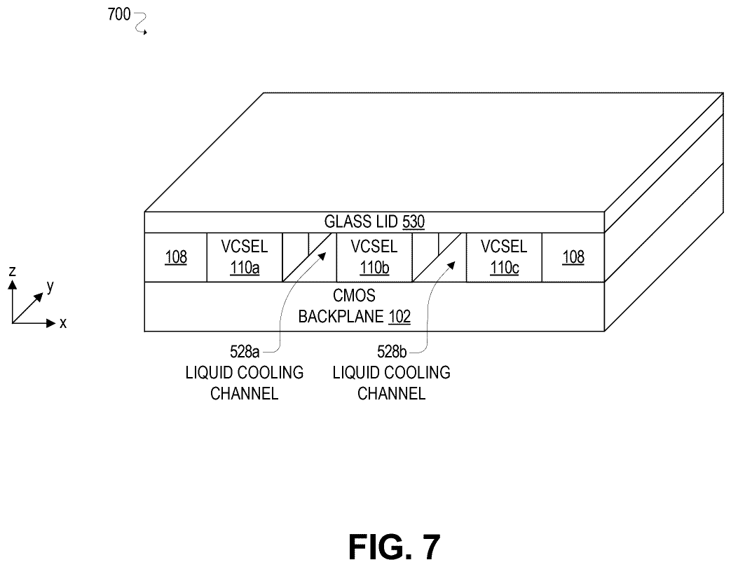

FIG. 7 illustrates a perspective view of an example micro-VCSEL array 700 with liquid cooling channels 528. In some embodiments, for example, micro-VCSEL array 700 may be similar to micro-VCSEL array 500. In the illustrated embodiment, VCSEL array 700 includes a CMOS backplane 102 (e.g., an IC/semiconductor die containing CMOS circuitry for controlling the VCSELs 110a-c), an array of micro-VCSELs 110a-c with liquid cooling channels 528a,b between them for heat dissipation, and a glass lid 530 over the channels 528. The channels 528 are hollow passages extending through the VCSEL array 700, with openings on each end to enable liquid to flow in and out of the channels 528, thus cooling the VCSELs 110. The glass lid 530 covers the top of the channels 528 to contain liquid within the channels 528 and prevent leaks, while also allowing light beams emitted by VCSELs 110 to propagate through the lid 530. In some embodiments, the glass lid 530 may include additional features (not shown), such as lenses to manipulate the light beams emitted by VCSELs 110.

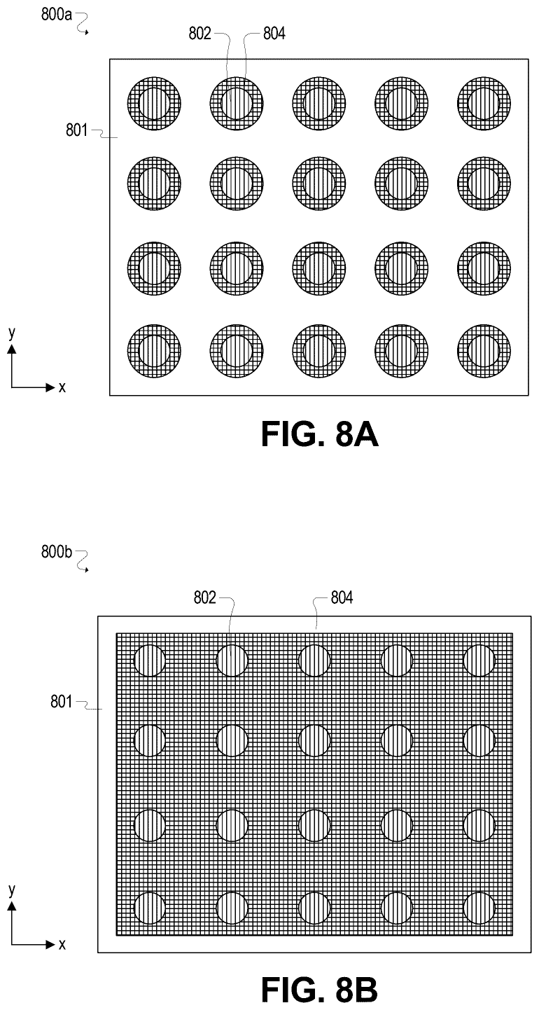

FIGS. 8A-B illustrate plan views (x-y plane) of example micro-VCSEL arrays 800a,b with integrated heat sinks 804. In particular, FIG. 8A illustrates a micro-VCSEL array 800a on a substrate 801 with integrated heat sinks 804 surrounding each VCSEL 802, where each heat sink 804 includes a hole (e.g., an opening or aperture) through which a corresponding VCSEL 802 emit laser beams. FIG. 8B illustrates a micro-VCSEL array 800b on a substrate 801 with a single monolithic integrated heat sink 804 surrounding the VCSELs 802, where the heat sink 804 includes holes (e.g., openings or apertures) through which corresponding VCSELs 802 emit laser beams. In some embodiments, VCSEL arrays 800a,b, and the associated VCSELs 802, may be implemented using any of the VCSEL embodiments described herein (e.g., VCSEL arrays 100, 300, 500, 700, 800a,b, VCSELs 110).

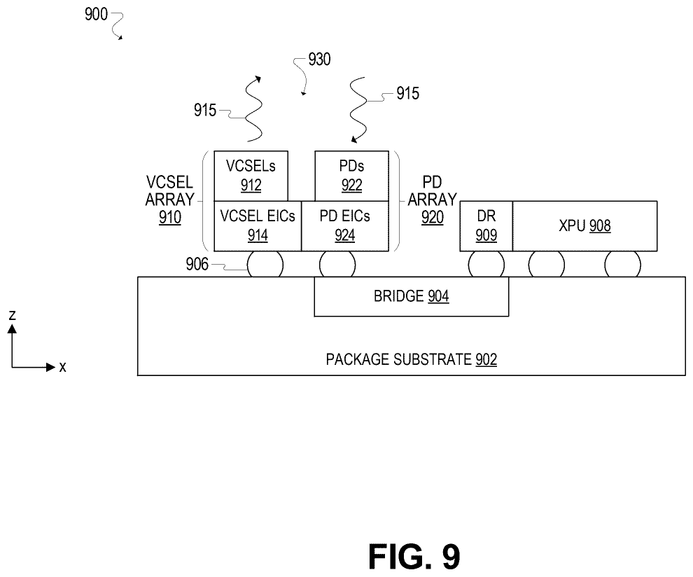

FIG. 9 illustrates a cross-section view (x-z plane) of an example system 900 with a micro-VCSEL array 910 according to certain embodiments. In the illustrated embodiment, system 900 includes a package substrate 902 with an embedded interconnect bridge (EMIB) die 904, along with an XPU 908 (and associated driver circuitry 909) and an optical interface 930. The XPU 908 and the optical interface 930 are electrically coupled to the package substrate 902, and the embedded bridge 904, via interconnect 906 (e.g., a ball grid array (BGA) interconnect with microbumps). Further, the XPU 908 and the optical interface 930 are electrically coupled to each other via the embedded bridge 904. Moreover, in some embodiments, the XPU 908 may use the optical interface 930 for optical communication and input/output (I/O), as described further below.

The optical interface 930 includes a VCSEL array 910 for sending optical signals 915 and a photodetector (PD) array 920 for receiving optical signals 915. The VCSEL array 910 includes an array of VCSELs 912 and corresponding VCSEL EICs 914. The VCSELs 912 may be used to generate or emit laser beams 915, and the VCSEL EICs 914 may include CMOS driver circuitry to control the VCSELs 912. In the illustrated embodiment, the VCSEL array 910 includes VCSEL EICs 914 for the respective VCSELs 912 in the array 910. In this manner, every VCSEL 912 in the VCSEL array 910 is individually addressable or controllable by a corresponding EIC driver circuit 914. Similarly, the PD array 920 includes PD EICs 924 for the respective PDs 912 in the array 920. In this manner, every PD 922 in the PD array 920 is individually addressable or controllable by a corresponding EIC driver circuit 924. In some embodiments, VCSEL array 910 may be implemented using any of the VCSEL embodiments described herein, including VCSEL arrays 100, 300, 500, 700, 800a,b. The PD array 920 includes an array of photodetectors (PDs) 922 and corresponding PD EICs 924. The PDs 922 may be used to detect or receive laser beams 915, and the PD EICs 924 may include CMOS driver circuitry to control the PDs 922.

In some embodiments, the optical interface 930 may be used for optical communication and I/O (e.g., parallel optical I/O). For example, the VCSELs 912 and PDs 922 may be optically coupled to one or more components (not shown) through one or more optical waveguides (not shown), such as a fiber array unit (e.g., an array of optical/glass fibers). Moreover, the XPU 908 may communicate optically with those components via optical interface 930.

In various embodiments, XPU 908 may include any type or combination of processing circuitry, including, without limitation, one or more of a system-on-a-chip (SoC), processor cores, central processing units (CPUs), graphics processing units (GPUs), vision processing units (VPUs), neural processing units (NPUs), field-programmable gate arrays (FPGAs), and application-specific integrated circuits (ASICs), among other examples. Alternatively, in other embodiments, the XPU 908 may be replaced with other components that use optical interface 930 for optical I/O, such as an integrated circuit die or package containing memory, storage, and/or communication circuitry (e.g., random access memory (RAM), persistent storage devices, network interface controllers (NICs)). In the illustrated embodiment, XPU 908 also includes driver circuitry 909 to control the optical interface 930.

System 900 may also be referred to herein as an integrated circuit (IC), IC device, IC package, semiconductor device or assembly, microelectronic device or assembly, computing device or system, electronic device or system, and so forth. In some embodiments, system 900 may be attached to a printed circuit board (PCB) (e.g., PCB 1102) and/or incorporated into an electronic device or system (e.g., device 1200), such as a cell phone, a wearable device, a computer, a server, a camera, a video playback device, a video game console, a display device, a vehicle control unit, or an appliance. System 900 may also include a variety of other components (not shown), such as memory, input/output (I/O) devices (e.g., display, keyboard, mouse, sensors), communication interfaces, antennas, etc.

### Example Integrated Circuit Embodiments

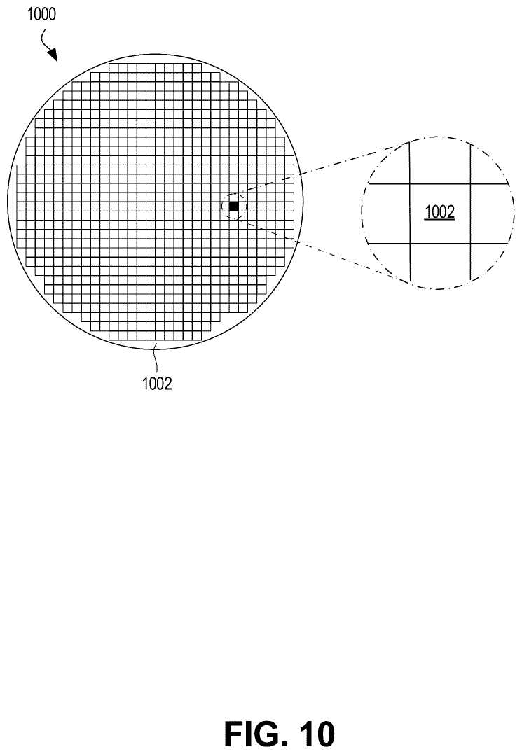

FIG. 10 is a top view of a wafer 1000 and dies 1002 that may be included in, or may include, any of the embodiments disclosed herein. In some embodiments, for example, the dies 1002 may include one or more VCSELs, VCSEL arrays, and/or associated integrated circuit components according to any of the embodiments described herein (e.g., VCSELs 110, 912, VCSEL arrays 100, 300, 500, 700, 800a,b, 910, CMOS backplane circuitry 102, 914, XPU 908).

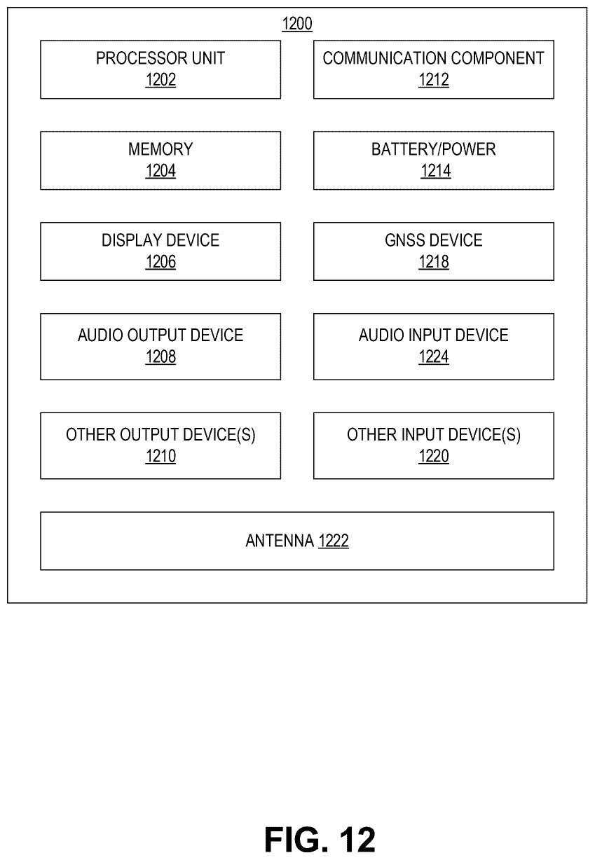

The wafer 1000 may be composed of semiconductor material and may include one or more dies 1002 having integrated circuit structures formed on a surface of the wafer 1000. The individual dies 1002 may be a repeating unit of an integrated circuit product that includes any suitable integrated circuit. After the fabrication of the semiconductor product is complete, the wafer 1000 may undergo a singulation process in which the dies 1002 are separated from one another to provide discrete “chips” of the integrated circuit product. The die 1002 may be any of the dies disclosed herein. The die 1002 may include one or more transistors, supporting circuitry to route electrical signals to the transistors, passive components (e.g., signal traces, resistors, capacitors, or inductors), and/or any other integrated circuit components. In some embodiments, the wafer 1000 or the die 1002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1002. For example, a memory array formed by multiple memory devices may be formed on a same die 1002 as a processor unit (e.g., the processor unit 1202 of FIG. 12) or other logic that is configured to store information in the memory devices or execute instructions stored in the memory array. Various ones of the microelectronic assemblies disclosed herein may be manufactured using a die-to-wafer assembly technique in which some dies are attached to a wafer 1000 that include others of the dies, and the wafer 1000 is subsequently singulated.

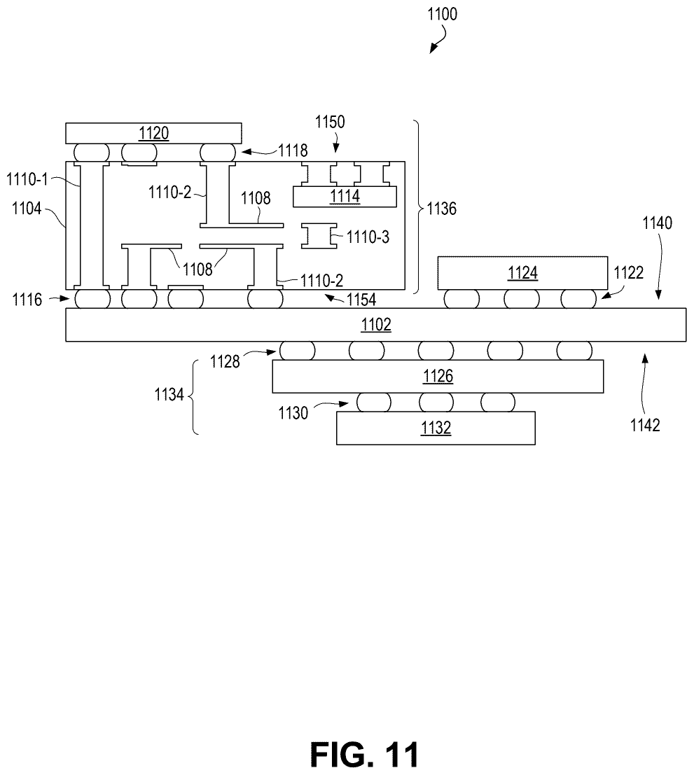

FIG. 11 is a cross-sectional side view of an integrated circuit device assembly 1100 that may include any of the embodiments disclosed herein. In some embodiments, for example, the embedded devices 1114 and/or IC components 1120, 1124, 1126, 1132 of the integrated circuit device assembly 1100 may include one or more one or more VCSELs (e.g., VCSELs 110, 912), VCSEL arrays (e.g., VCSEL arrays 100, 300, 500, 700, 800a,b, 910), and/or associated integrated circuit components (e.g., CMOS backplane circuitry 102, 914, XPU 908) according to any of the embodiments described herein.

In some embodiments, the integrated circuit device assembly 1100 may be a microelectronic assembly. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142. Any of the integrated circuit components discussed below with reference to the integrated circuit device assembly 1100 may take the form of any suitable ones of the embodiments of the microelectronic assemblies disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit product that includes one or more integrated circuit dies (e.g., the die 1002 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include one or more of the embodiments disclosed herein. For example, any suitable ones of the components of the electrical device 1200 may include one or more of the VCSELs (e.g., VCSELs 110, 912), VCSEL arrays (e.g., VCSEL arrays 100, 300, 500, 700, 800a,b, 910), CMOS components (e.g., CMOS backplane circuitry 102, 914, XPU 908), systems 900, integrated circuit device assemblies 1100, integrated circuit components 1120, or integrated circuit dies 1002 disclosed herein.

A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include other output device(s) 1210 (or corresponding interface circuitry, as discussed above). Examples of the other output device(s) 1210 may include an audio codec, a video codec, a printer, a wired or wireless transmitter for providing information to other devices, or an additional storage device.

The electrical device 1200 may include other input device(s) 1220 (or corresponding interface circuitry, as discussed above). Examples of the other input device(s) 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a display device (e.g., monitor, television), a set-top box, an entertainment control unit, a video game console, a video playback device, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data.

In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

The terms “substantially,” “close,” “approximately,” “near,” and “about,” generally refer to being within +/−10% of a target value (unless otherwise specified). Similarly, terms describing spatial relationships, such as “perpendicular,” “orthogonal,” or “coplanar,” may refer to being substantially within the described spatial relationships (e.g., within +/−10 degrees of orthogonality).

Certain terminology may also be used in the foregoing description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The terms “over”, “between”, “adjacent”, “to”, and “on” as used herein may refer to a relative position of one layer or component with respect to other layers or components. For example, one layer “over” or “on” another layer, “adjacent” to another layer, or bonded “to” another layer may be directly in contact with the other layer or may have one or more intervening layers. One layer “between” layers may be directly in contact with the layers or may have one or more intervening layers.

The meaning of “a,” “an,” and “the” include plural references. The meaning of “in” includes “in” and “on.”

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. In some cases, a small printed circuit board may be used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and/or metallization structures. The substrate may mechanically support and electrically couple one or more IC dies on a single platform, with encapsulation of the one or more IC dies by a moldable dielectric material. The substrate generally comprises solder bumps as bonding interconnects on both sides. One side of the substrate, generally referred to as the “die side”, may comprise solder bumps for chip or die bonding. The opposite side of the substrate, generally referred to as the “land side”, may comprise solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal.

### Examples

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a laser, comprising: a plurality of mirrors including a first mirror and a second mirror, wherein at least one of the first mirror or the second mirror comprises a metasurface mirror; and one or more quantum wells between the first mirror and the second mirror.

Example 2 includes the laser of Example 1, wherein: the first mirror comprises the metasurface mirror; and the second mirror comprises a distributed Bragg reflector mirror.

Example 3 includes the laser of Example 1, wherein: the first mirror comprises the metasurface mirror, wherein the metasurface mirror is a first metasurface mirror; and the second mirror comprises a second metasurface mirror.

Example 4 includes the laser of any of Examples 1-3, wherein: the first mirror is over the one or more quantum wells and the second mirror is under the one or more quantum wells; and the first mirror has at least 95% reflectivity and the second mirror has at least 99% reflectivity.

Example 5 includes the laser of any of Examples 1-4, wherein the metasurface mirror comprises a plurality of nanoparticles, wherein the nanoparticles comprise properties that provide at least 95% reflectivity.

Example 6 includes the laser of Example 5, wherein the properties comprise size, shape, material, and arrangement of the respective nanoparticles.

Example 7 includes the laser of any of Examples 5-6, wherein at least some of the nanoparticles comprise a dielectric and/or a metal.

Example 8 includes the laser of any of Examples 5-7, wherein at least some of the nanoparticles comprise: gold; silver; aluminum; copper; titanium; silicon; silicon and nitrogen; silicon and oxygen; titanium and oxygen; gallium and nitrogen; gallium and arsenic; or indium and phosphorous.

Example 9 includes the laser of any of Examples 1-8, further comprising a vertical-cavity surface-emitting laser (VCSEL), wherein the VCSEL comprises the plurality of mirrors and the one or more quantum wells.

Example 10 includes the laser of Example 9, further comprising at least one of: a heat sink over the VCSEL, wherein the heat sink comprises a metal layer, and wherein the metal layer comprises an aperture through which the VCSEL emits light; a thermal via adjacent to the VCSEL, wherein the thermal via is coupled to ground; or a channel adjacent to the VCSEL, wherein the channel is hollow, and wherein liquid is to flow through the channel.

Example 11 includes the laser of Example 10, further comprising a glass lid over the channel.

Example 12 includes the laser of any of Examples 9-11, wherein the VCSEL further comprises a first conductive contact and a second conductive contact, wherein the first conductive contact is electrically coupled to a semiconductor die, and wherein the second conductive contact is electrically coupled to ground.

Example 13 includes the laser of Example 12, wherein the first conductive contact comprise an anode, and wherein the second conductive contact comprises a cathode.

Example 14 includes the laser of any of Examples 12-13, wherein the semiconductor die comprises complementary metal-oxide-semiconductor (CMOS) backplane circuitry to control the VCSEL.

Example 15 includes the laser of any of Examples 9-14, wherein the VCSEL further comprises p-type cladding and n-type cladding, wherein the p-type cladding is under the one or more quantum wells, and wherein the n-type cladding is over the one or more quantum wells.

Example 16 includes the laser of any of Examples 1-15, further comprising a VCSEL array, wherein the VCSEL array comprises a plurality of VCSELs, wherein individual VCSELs comprise an instance of the plurality of mirrors and the one or more quantum wells.

Example 17 includes an electronic device, comprising: a vertical-cavity surface-emitting laser (VCSEL) array, wherein the VCSEL array comprises a plurality of VCSELs, wherein individual VCSELs comprise: a plurality of mirrors, wherein at least one of the mirrors comprises a metamirror; and an active region between the mirrors, wherein the active region comprises one or more quantum wells; an integrated circuit (IC) die electrically coupled to the VCSEL array, wherein the IC die comprises circuitry to control the VCSEL array.

Example 18 includes the electronic device of Example 17, wherein at least one of the mirrors comprises a distributed Bragg reflector mirror or a second metamirror.

Example 19 includes the electronic device of any of Examples 17-18, wherein the metamirror comprises a plurality of nanoparticles, wherein the nanoparticles comprise a design that provides at least 95% reflectivity.

Example 20 includes the electronic device of Example 19, wherein the design comprises size, shape, material, and arrangement of the respective nanoparticles.

Example 21 includes the electronic device of any of Examples 17-20, wherein the VCSEL array further comprises one or more heat sinks over the VCSELs, wherein the one or more heat sinks comprise openings through which the VCSELs emit laser beams.

Example 22 includes the electronic device of any of Examples 17-21, wherein the VCSEL array further comprises a plurality of thermal vias between the VCSELs, wherein the thermal vias are coupled to ground.

Example 23 includes the electronic device of any of Examples 17-20, wherein the VCSEL array further comprises: a plurality of channels between the VCSELs, wherein the channels are hollow, and wherein liquid is to flow through the channels; and a glass lid over the channels.

Example 24 includes the electronic device of any of Examples 17-23, wherein: the VCSEL array and the IC die are electrically coupled via a hybrid dielectric and metal bond; and the IC die comprises a plurality of electronic integrated circuits (EICs) to control the plurality of VCSELs, wherein individual VCSELs are individually controllable by one of the EICs.

Example 25 includes the electronic device of any of Examples 17-24, wherein the electronic device is an IC package.

Example 26 includes the electronic device of any of Examples 17-24, further comprising: a circuit board; and an IC package electrically coupled to the circuit board, wherein the IC package comprises the VCSEL array and the IC die.

Example 27 includes the electronic device of any of Examples 25-26, wherein: the IC die is a first IC die; and the IC package further comprises a second IC die, wherein the second IC die is electrically coupled to the first IC die, wherein the second IC die is to communicate optically via the VCSEL array, and wherein the second IC die comprises processing circuitry, communication circuitry, or memory circuitry.

Example 28 includes the electronic device of any of Examples 17-27, wherein the electronic device is a cell phone, a wearable device, a computer, a server, a camera, a video playback device, a video game console, a display device, a vehicle control unit, or an appliance.

Example 29 includes a method, comprising: forming a plurality of surface-emitting lasers, wherein individual surface-emitting lasers comprise: an anode; a first mirror over the anode; p-type cladding over the anode; one or more quantum wells over the first mirror and the p-type cladding; n-type cladding over the one or more quantum wells; a second mirror over the one or more quantum wells, wherein the second mirror comprises a metamirror; and a cathode, wherein the cathode is adjacent to the n-type cladding and/or the second mirror; and forming a plurality of electrical connections between the surface-emitting lasers and a semiconductor substrate, wherein the semiconductor substrate comprises complementary metal-oxide-semiconductor (CMOS) circuitry.

Example 30 includes the method of Example 29, wherein forming the surface-emitting lasers and the electrical connections comprises: forming the n-type cladding over a carrier substrate; forming the one or more quantum wells over the n-type cladding; forming the p-type cladding over the one or more quantum wells; forming the first mirror over the one or more quantum wells; bonding the carrier substrate face down on the semiconductor substrate; releasing the carrier substrate; forming the second mirror over the one or more quantum wells; and forming the cathode adjacent to the n-type cladding and/or the second mirror.

Example 31 includes the method of any of Examples 29-30, further comprising: forming one or more heat sinks over the surface-emitting lasers, wherein the one or more heat sinks comprise openings through which the surface-emitting lasers emit laser beams; forming a plurality of thermal vias between the surface-emitting lasers, wherein the thermal vias are coupled to ground; or forming a plurality of channels between the surface-emitting lasers, wherein the channels are hollow, and wherein liquid is to flow through the channels.

Example 32 includes the method of any of Examples 29-31, wherein the method is a method of forming a laser array, wherein the laser array comprises the plurality of surface-emitting lasers and the semiconductor substrate.

1. A laser, comprising:
a plurality of mirrors including a first mirror and a second mirror, wherein at least one of the first mirror or the second mirror comprises a metasurface mirror; and
one or more quantum wells between the first mirror and the second mirror.

2. The laser of claim 1, wherein:
the first mirror comprises the metasurface mirror; and
the second mirror comprises a distributed Bragg reflector mirror.

3. The laser of claim 1, wherein:
the first mirror comprises the metasurface mirror, wherein the metasurface mirror is a first metasurface mirror; and
the second mirror comprises a second metasurface mirror.

4. The laser of claim 1, wherein:
the first mirror is over the one or more quantum wells and the second mirror is under the one or more quantum wells; and
the first mirror has at least 95% reflectivity and the second mirror has at least 99% reflectivity.

5. The laser of claim 1, wherein the metasurface mirror comprises a plurality of nanoparticles, wherein the nanoparticles comprise properties that provide at least 95% reflectivity.

6. The laser of claim 5, wherein at least some of the nanoparticles comprise:
gold;
silver;
aluminum;
copper;
titanium;
silicon;
silicon and nitrogen;
silicon and oxygen;
titanium and oxygen;
gallium and nitrogen;
gallium and arsenic; or
indium and phosphorous.

7. The laser of claim 1, further comprising a vertical-cavity surface-emitting laser (VCSEL), wherein the VCSEL comprises the plurality of mirrors and the one or more quantum wells.

8. The laser of claim 7, further comprising at least one of:
a heat sink over the VCSEL, wherein the heat sink comprises a metal layer, and wherein the metal layer comprises an aperture through which the VCSEL emits light;
a thermal via adjacent to the VCSEL, wherein the thermal via is coupled to ground; or
a channel adjacent to the VCSEL, wherein the channel is hollow, and wherein liquid is to flow through the channel.

9. The laser of claim 7, wherein the VCSEL further comprises a first conductive contact and a second conductive contact, wherein the first conductive contact is electrically coupled to a semiconductor die, and wherein the second conductive contact is electrically coupled to ground.

10. The laser of claim 7, wherein the VCSEL further comprises p-type cladding and n-type cladding, wherein the p-type cladding is under the one or more quantum wells, and wherein the n-type cladding is over the one or more quantum wells.

11. An electronic device, comprising:
a vertical-cavity surface-emitting laser (VCSEL) array, wherein the VCSEL array comprises a plurality of VCSELs, wherein individual VCSELs comprise:
a plurality of mirrors, wherein at least one of the mirrors comprises a metamirror; and
an active region between the mirrors, wherein the active region comprises one or more quantum wells;
an integrated circuit (IC) die electrically coupled to the VCSEL array, wherein the IC die comprises circuitry to control the VCSEL array.

12. The electronic device of claim 11, wherein at least one of the mirrors comprises a distributed Bragg reflector mirror or a second metamirror.

13. The electronic device of claim 11, wherein the VCSEL array further comprises one or more heat sinks over the VCSELs, wherein the one or more heat sinks comprise openings through which the VCSELs emit laser beams.

14. The electronic device of claim 11, wherein the VCSEL array further comprises a plurality of thermal vias between the VCSELs, wherein the thermal vias are coupled to ground.

15. The electronic device of claim 11, wherein the VCSEL array further comprises:
a plurality of channels between the VCSELs, wherein the channels are hollow, and wherein liquid is to flow through the channels; and
a glass lid over the channels.

16. The electronic device of claim 11, wherein:
the VCSEL array and the IC die are electrically coupled via a hybrid dielectric and metal bond; and
the IC die comprises a plurality of electronic integrated circuits (EICs) to control the plurality of VCSELs, wherein individual VCSELs are individually controllable by one of the EICs.

17. The electronic device of claim 11, wherein:
the IC die is a first IC die; and
the electronic device further comprises:
a circuit board; and
an IC package electrically coupled to the circuit board, wherein the IC package comprises the VCSEL array, the first IC die, and a second IC die, wherein the second IC die is electrically coupled to the first IC die, wherein the second IC die is to communicate optically via the VCSEL array, and wherein the second IC die comprises processing circuitry, communication circuitry, or memory circuitry.

18. A method, comprising:
forming a plurality of surface-emitting lasers, wherein individual surface-emitting lasers comprise:
an anode;
a first mirror over the anode;
p-type cladding over the anode;
one or more quantum wells over the first mirror and the p-type cladding;
n-type cladding over the one or more quantum wells;
a second mirror over the one or more quantum wells, wherein the second mirror comprises a metamirror; and
a cathode, wherein the cathode is adjacent to the n-type cladding and/or the second mirror; and
forming a plurality of electrical connections between the surface-emitting lasers and a semiconductor substrate, wherein the semiconductor substrate comprises complementary metal-oxide-semiconductor (CMOS) circuitry.

19. The method of claim 18, wherein forming the surface-emitting lasers and the electrical connections comprises:
forming the n-type cladding over a carrier substrate;
forming the one or more quantum wells over the n-type cladding;
forming the p-type cladding over the one or more quantum wells;
forming the first mirror over the one or more quantum wells;
bonding the carrier substrate face down on the semiconductor substrate;
releasing the carrier substrate;
forming the second mirror over the one or more quantum wells; and
forming the cathode adjacent to the n-type cladding and/or the second mirror.

20. The method of claim 18, wherein the method is a method of forming a laser array, wherein the laser array comprises the plurality of surface-emitting lasers and the semiconductor substrate.
